(19) United States
(12) Patent Application Publication
(10) Pub. No.: US 2025/0275449 A1
(43) Pub. Date: Aug. 28, 2025

(54) DISPLAY DEVICE

(71) Applicant: LG Display Co., Ltd., Seoul (KR)

(72) Inventors: Jinuk LEE, Seoul (KR); ChangEun KIM, Paju-si (KR)

(73) Assignee: LG Display Co., Ltd., Seoul (KR)

(21) Appl. No.: 18/924,788

(22) Filed: Oct. 23, 2024

(30) Foreign Application Priority Data
Feb. 27, 2024 (KR) 10-2024-0028370

(51) Int. Cl. H10K 59/80; H10K 59/126; H10K 59/50; H10K 102/00

(52) U.S. Cl. CPC H10K 59/8792; H10K 59/126; H10K 59/50; H10K 2102/351

(57) ABSTRACT

A display device can include an array substrate, an inorganic black matrix disposed on the array substrate, and a thin film transistor disposed on the inorganic black matrix. At least a portion of the inorganic black matrix overlaps the thin film transistor, and the inorganic black matrix includes a first black matrix layer on the array substrate and a second black matrix layer on the first black matrix layer. Further, the first black matrix layer includes metal oxide, a reflective index n of the first black matrix layer is 2.1-2.5, and an absorption coefficient k of the first black matrix layer is 0.4-0.6.

### CROSS-REFERENCE TO RELATED APPLICATIONS

This application claims priority to Korean Patent Application No. 10-2024-0028370 filed on Feb. 27, 2024, in the Korean Intellectual Property Office, the entire contents of which is hereby expressly incorporated by reference into the present application.

### BACKGROUND

### Field

The present disclosure relates to a display device, and particularly, a display device that secures improvement in visual reflectance.

### Discussion of the Related Art

In the information era, the field of displays displaying electric information signals visually has made a rapid progress. Here, a variety of display devices that are thin and lightweight ensure less power consumption and provide excellent performance have been developed. Display devices can include a liquid crystal display (LCD) device, an organic light emitting display (OLED) device and the like.

In recent years, research has been conducted into a flip-over-type display device where a substrate on which a thin film transistor is disposed is used as a viewing surface. In particular, in the case of a flip-over-type display device, since the substrate having the thin film transistor disposed thereon is configured as an upper substrate, a pad part is disposed toward the back surface of a panel. This makes it possible to remove a structure such as an exterior cover for covering the pad part, and embody a four-surface borderless display device.

However, in the case where the substrate having the thin film transistor disposed thereon is used as a viewing surface, a contrast ratio can deteriorate in the outer portion of the panel having a high reflectance due to a plurality of metal lines, metal electrodes and the like. In this case, to reduce the reflectance, a polarization layer is provided in the flip-over-type display device.

In the case where the polarization layer is provided, the reflectance can decrease and a contrast ratio can improve. However, since the polarization layer is an expensive component, technologies for reducing the reflectance of external light without using a polarization layer is needed to be developed to reduce costs.

### SUMMARY OF THE DISCLOSURE

An objective of the present disclosure is to provide a display device that can prevent the visibility of reflected light by a user, which can be caused by a high reflectance of components such as lines, electrodes and the like.

Another objective of the present disclosure is to provide a display device that can address or prevent deterioration in contrast ratios without using an expensive polarization layer.

An objective of the present disclosure is to provide a borderless display device where the width of a bezel area can be minimized while deterioration in contrast ratios, which can be caused by components formed of metal and viewed by a user, can be resolved, in a flip-over-type display device where a substrate, on which a thin film transistor is disposed, is used as a viewing surface.

Objects of the present disclosure are not limited to the above-mentioned objects, and other objects, which are not mentioned above, can be clearly understood by those skilled in the art from the following descriptions.

A display device of one embodiment of the present disclosure comprises an array substrate, an inorganic black matrix disposed on the array substrate, and a thin film transistor disposed on the inorganic black matrix, wherein at least a portion of the inorganic black matrix overlaps the thin film transistor, the inorganic black matrix comprises a first black matrix layer on the array substrate and a second black matrix layer on the first black matrix layer, and the first black matrix layer comprises metal oxide, a reflective index n of the first black matrix layer is 2.1-2.5 and an absorption coefficient k of the first black matrix layer is 0.4-0.6.

Other detailed matters of the example embodiments are included in the detailed description and the drawings.

In one embodiment of the present disclosure, provided is a display device in which reflectance can decrease without a polarization layer and an excellent contrast ratio can be secured. Accordingly, provided is a display device that can secure a decrease in costs since the display device is not provided with an expensive polarization layer, and secure excellent display quality.

In one embodiment of the present disclosure, in the case of flip-over-type display device where a substrate, on which a thin film transistor is disposed, is used as a viewing surface, provided is a borderless display device in which the width of a bezel area can be minimized while deterioration in contrast ratios, caused by components formed of a material of high reflectivity and viewed by the user, can be resolved.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view of a display device of one embodiment of the present disclosure;

FIG. 2 is a cross-sectional view of a display device of another embodiment of the present disclosure;

FIG. 3 is a cross-sectional view of a display device of yet another embodiment of the present disclosure; and

FIG. 4 is a graph showing reflectance of the wavelength of each of Comparative examples 1-3 and Embodiment 1 of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure. Further, the term “can” fully encompasses all the meanings and coverages of the term “may.”

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiment of the present disclosure are operatively coupled and configure.

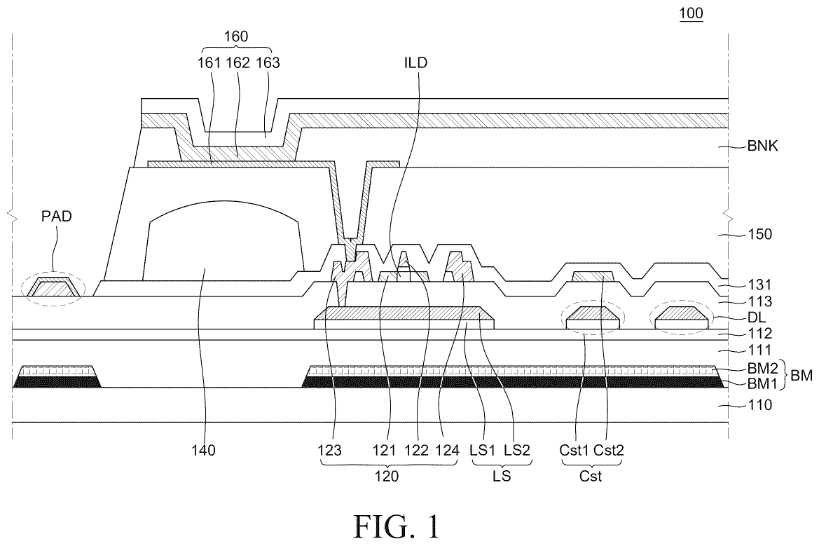

FIG. 1 is a cross-sectional view of a display device of one embodiment of the present disclosure.

Referring to FIG. 1, a display device 100 comprises an array substrate 110, an inorganic black matrix BM, an organic film 111, a first buffer layer 112, a light shielding layer LS, a second buffer layer 113, a thin film transistor 120, a passivation layer 131, a color filter 140, a planarization layer 150 and a light emitting element 160.

The array substrate 110 supports components constituting the display device 100. The array substrate 110 can be made of an insulation material. For example, the array substrate 110 can be made of a glass substrate. Specifically, the array substrate 110, for example, can be a single-layer glass substrate.

The array substrate 110 comprises areas defined as a display area and a non-display area. The display area is an area that displays an image. In the display area, a plurality of sub pixels for displaying an image, and a driving circuit for driving the plurality of sub pixels can be disposed. Each of the plurality of sub pixels is an individual unit emitting light, and in each of the plurality of sub pixels, the light emitting element 160 is formed.

The plurality of sub pixels can comprise a red sub pixel, a green sub pixel and a blue sub pixel, but not be limited thereto. The driving circuit can comprise a variety of transistors, storage capacitors, lines and the like for driving the plurality of sub pixels. The driving circuit, for example, can be comprised of various types of components such as a driving transistor, a switching transistor, a sensing transistor, a storage capacitor, a gate line, a data line and the like, but not limited thereto.

The non-display area is disposed to surround the display area and is an area that does not display an image substantially. In the non-display area, a variety of lines, driving ICs and the like for driving the sub pixels disposed in the display area are disposed. For example, in the non-display area, a variety of driving ICs such as a gate driver IC, a data driver IC and the like can be disposed, but not limited thereto.

The inorganic black matrix BM is disposed on the array substrate 110. The inorganic black matrix BM is disposed to contact the array substrate 110 directly. At this time, reflectance can decrease further, securing improvement in display quality. The inorganic black matrix BM is formed of a material absorbing light and absorbs unnecessary light. For example, the inorganic black matrix BM can be disposed to overlap a light shielding layer LS, a thin film transistor 120, a capacitor Cst, various types of lines and the like. The inorganic black matrix BM, for example, can be disposed to correspond to an area of the light emitting element 160 except for a light emitting area thereof described hereinafter. Accordingly, the inorganic black matrix BM can prevent components such as a thin film transistor 120, a capacitor Cst, a pad part PAD, a variety of lines DL or a planarization layer 150 and the like that have high reflectance from being reflected by external light and viewed by the user. Further, the inorganic black matrix BM can prevent deterioration in a contrast ratio, caused by reflected light, thereby maintaining display quality at a high level.

The inorganic black matrix BM can have a multi-layer structure comprising a first black matrix layer BM1 and a second black matrix layer BM2. The first black matrix layer BM1 is disposed on the array substrate 110, and the second black matrix layer BM2 is stacked on the first black matrix layer BM1. As the first black matrix layer BM1 and the second black matrix layer BM2 are stacked as described above, reflectance can decrease further, a more excellent contrast ratio can be secured, and the thin film transistor 120, the capacitor Cst, a variety of lines DL, and the like can be effectively prevented from being reflected and viewed.

The first black matrix layer BM1 adjacent to the array substrate 110 is formed of a material having low reflection properties. For example, the first black matrix layer BM1 can be formed of a metal oxide having a refractive index n from 2.1-2.5 and an absorption coefficient k of 0.4-0.6. In the case where the refractive index n and absorption coefficient k of the first black matrix layer BM1 are within the above-described ranges, reflectance is low in a wide wavelength band, making it possible to provide a display device of high quality.

For example, the first black matrix layer BM1 can be formed of a metal oxide comprising molybdenum oxide (MoOₓ) and niobium oxide (Nb₂O₅). In the case where such a metal oxide is used, the refractive index and absorption coefficient can be easily adjusted to a refractive index and an absorption coefficient within the above-described ranges, resulting in a reduction in the reflectance of external light and securing improvement in display quality.

For example, the first black matrix layer BM1 can comprise 70-85 wt % of molybdenum oxide (MoOₓ), and 15-30 wt % of niobium oxide (Nb₂O₅) with respect to a total of 100 wt % of metal oxide. In another example, the first black matrix layer BM1 can comprise 75-80 wt % of molybdenum oxide (MoOₓ), and 20-25 wt % of niobium oxide (Nb₂O₅) with respect to a total of 100 wt % of metal oxide. Since the refractive index and the absorption coefficient are within the above-described range, reflectance is low, and an excellent contrast ratio is secured without a polarization layer that is an expensive component. In the case where the content of niobium oxide (Nb₂O₅) is at greater than 30 wt %, processability can deteriorate.

The second black matrix layer BM2 can be formed of metal having low reflection properties. For example, the second black matrix layer BM2 can be formed of metal selected from molybdenum (Mo), titanium (Ti) and an alloy thereof. Since the second black matrix layer BM2 formed of such metal, and the first black matrix layer BM1 formed of the above-described metal oxide are configured to be stacked, reflectance decreases further, a more excellent contrast ratio is secured, and the visibility of the electrodes and lines of the thin film transistor 120 and the like can be minimized, thereby providing a display device of high quality.

For example, the thickness of the first black matrix layer BM1 can be 300 Å-700 Å. In the case where the thickness of the first black matrix layer BM1 is within the above-described range, reflectance can decrease further. In the case where the thickness of the first black matrix layer BM1 is less than 300 Å, reflectance in a long wavelength band can increase, and in the case where the thickness of the first black matrix layer BM1 is greater than 700 Å, reflectance in a short wavelength band can increase.

For example, the thickness of the second black matrix layer BM2 can be 500 Å-3000 Å. Within the above-described range, reflectance is low in a wide wavelength area advantageously.

The organic film 111 is disposed on the inorganic black matrix BM. The organic film 111 can provide a planar surface by covering the upper surface of the inorganic black matrix BM and protect the display device 100 from an external impact.

For example, the organic film 111 can comprise one or more sorts selected from siloxane resin and polyimide. The materials have excellent heat resistance and provide a planar surface, making it easier to form components such as a thin film transistor 120 on the organic film 111.

For example, the thickness of the organic film 111 can be 2 μm to 3 μm. In the case where the thickness of the organic film 111 is within the above-described range, the organic film 111 can sufficiently cover the inorganic black matrix BM and provide a planar surface.

The first buffer layer 112 is disposed on the organic film 111. The first buffer layer 112 protects the thin film transistor 120 and the light emitting element 160 from moisture, external air, foreign substances and the like infiltrating from the outside. Additionally, the first buffer layer 112 prevents a change in the properties of the thin film transistor 120, caused by the dispersion of hydrogen or foreign substances and the like from the array substrate 110, in the process of forming the thin film transistor. The first buffer layer 112 can be formed of an inorganic insulation material. For example, the first buffer layer 112 can be formed of a material selected from a silicon oxide film, a silicon nitride film and a silicon oxynitride film, but not limited thereto. The first buffer layer 112 can have a single-layer structure or a multi-layer structure. For example, the first buffer layer 112 can have a multi-layer structure in which a silicon oxide film and a silicon nitride film are stacked, but not be limited thereto.

The light shielding layer LS can be disposed on the first buffer layer 112. The light shielding layer LS prevents light-induced damage to the thin film transistor 120, in particular, to an active layer 121, by blocking light such as ultraviolet rays and the like. Accordingly, the light shielding layer LS is disposed to overlap the active layer 121 of the thin film transistor 120.

As illustrated in FIG. 1, in the case of a thin film transistor 120 having a structure in which a gate electrode 122 is disposed on the active layer 121, the active layer 121 can be damaged by ultraviolet rays input from the outside. The light shielding layer LS can be disposed between the array substrate 110 and the active layer 121 and protect the active layer 121 from ultraviolet rays.

The light shielding layer LS can be made of a metallic material. Since the light shielding layer LS is made of a metallic material, the active layer 121 can be protected from ultraviolet rays, but reflectance is high, causing deterioration in the contrast ratio of the display device 100. To minimize deterioration in the contrast ratio of the display device, the light shielding layer LS can comprise metal of low reflectivity. The light shielding layer LS, for example, can comprise one sort of metal selected from copper (Cu), molybdenum (Mo), aluminum (Al), chromium (Cr), gold (Au), titanium (Ti), nickel (Ni) and niobium (Nd), but not be limited thereto.

The light shielding layer LS can be formed of a single layer or multiple layers. Referring to FIG. 1, the light shielding layer LS can comprise a first layer LS1, and a second layer LS2 on the first layer LS1. At this time, the first layer LS1 can comprise metal of relatively low reflexibility to reduce the reflectance of external light. For example, the first layer LS1 can comprise one or more sorts of metal among molybdenum (Mo), titanium (Ti), nickel (Ni), copper (Cu) and tungsten (W). Additionally, to reduce reflectance further, the first layer (LS1) can further comprise metal oxide such as MoO₂, In₂O₃ and SnO₂, ZnO, Nb₂O₅, WO₃, TiO₂, ZrO₂ and HfO₂, but not be limited thereto.

The second layer LS2, for example, can comprise one sort of metal selected from copper (Cu), molybdenum (Mo), aluminum (Al), chromium (Cr), gold (Au), titanium (Ti), nickel (Ni) and niobium (Nd), but not be limited thereto.

In the drawing, the light shielding layer LS has a double-layer structure, but is not limited thereto, and the light shielding layer LS can be formed of a single layer or multiple layers that are triple or more layers.

Data lines DL and a lower capacitor electrode Cst1 of the same material as the light shielding layer LS can be respectively formed on the same surface as the light shielding layer LS, but not limited thereto. Depending on the design structure of the display device 100, the positions or the structures of the data lines DL and the lower capacitor electrode Cst1 can vary.

The second buffer layer 113 is disposed to cover the light shielding layer LS, the data lines DL and the lower capacitor electrode Cst1. The second buffer layer 113 insulates the light shielding layer LS and the thin film transistor 120. Additionally, the second buffer layer 113 insulates the lower capacitor electrode Cst1 and an upper capacitor electrode Cst2. Further, the second buffer layer 113 blocks impurities flowing in from the array substrate 110 and the light shielding layer LS in the process of forming the thin film transistor 120. For example, the second buffer layer 113 can be formed of a material selected from a silicon oxide film, a silicon nitride film and a silicon oxynitride film, but not limited thereto.

The thin film transistor 120 is disposed on the second buffer layer 113. The thin film transistor 120 comprises an active layer 121, a gate electrode 122, a source electrode 123 and a drain electrode 124.

The active layer 121 is disposed on the second buffer layer 113. As described above, the active layer 121 is disposed on the second buffer layer 113 in such a way that the active layer 121 overlaps the light shielding layer LS. Accordingly, damage to the active layer 121 caused by ultraviolet rays is prevented. The active layer 121 can be an oxide semiconductor layer made of an oxide semiconductor material.

The upper capacitor electrode Cst2 of the same material as the active layer 121 can be formed on the same surface as the active layer 121. The upper capacitor electrode Cst2 is disposed to overlap the lower capacitor electrode Cst1.

An insulation film ILD made of an insulation material is disposed on the active layer 121 and the upper capacitor electrode Cst2. The insulation film ILD is disposed between the active layer 121 and the gate electrode 122, and insulates them from each other. The insulation film ILD can be formed of a material selected from a silicon oxide film, a silicon nitride film and a silicon oxynitride film, but not limited thereto.

The gate electrode 122 made of an electrically conductive material such as metal is disposed on the insulation film ILD. The gate electrode 122 is disposed to overlap a channel area of the active layer 121. For example, the gate electrode 122 can be made of copper (Cu), aluminum (Al), molybdenum (Mo), nickel (Ni), titanium (Ti), chromium (Cr) or an alloy thereof, but not limited thereto.

The source electrode 123 and the drain electrode 124 can be disposed on the insulation film ILD, like the gate electrode 122. The source electrode 123 and the drain electrode 124 can be made of copper (Cu), aluminum (Al), molybdenum (Mo), nickel (Ni), titanium (Ti), chromium (Cr) or an alloy thereof, but not limited thereto. The source electrode 123 and the drain electrode 124 can be formed of the same material as the gate electrode 122 in the same process as the gate electrode 122, but not limited thereto.

Each of the source electrode 123 and the drain electrode 124 is disposed to electrically connect to the active layer 121. The source electrode 123 and the drain electrode 124 can respectively be disposed to contact both ends of the active layer 121 that is not covered by the insulation film IDL and exposed. For example, the source electrode 123 can be disposed to contact the end of one side of the active layer 121, and the drain electrode 124 can be disposed to contact the end of the other side of the active layer 123.

The source electrode 123 or the drain electrode 124 can be disposed to contact the light shielding layer LS through a contact hole formed at the second buffer layer 113. In the case where the light shielding layer LS is disposed to overlap the active layer 121, in the form of an island, parasitic capacitance can affect the performance of the thin film transistor 120. Accordingly, the light shielding layer LS connects to the source electrode 123 or the drain electrode 124 and supplies a voltage, to minimize the effect of the parasitic capacitance. However, the structure of the present disclosure is not limited to the above-described one and is variable depending on the structure and design of the thin film transistor 120. In another example, the thin film transistor 120 can be formed into a bottom gate-type thin film transistor where the gate electrode 122 is disposed under the active layer 121. At this time, the gate electrode 122 disposed under the active layer 121 can function as a light shielding layer.

The pad part PAD can be disposed in the outer portion of the array substrate 110. The pad part PAD can be disposed on the second buffer layer 113. The pad part PAD can be formed in a process the same as those of the source electrode 123, the drain electrode 124 and the gate electrode 122 for convenience of processing. Accordingly, the pad part PAD can be made of a material the same as those of the source electrode 123, the drain electrode 124 and the gate electrode 122, but not limited thereto.

The passivation layer 131 is disposed on the thin film transistor 120. The passivation layer 131 can prevent the degradation of the thin film transistor 120, caused by external moisture, oxygen and the like. For example, the passivation layer 131 can be formed of an inorganic insulation material such as a silicon oxide film, a silicon nitride film and the like, but not limited thereto. The passivation layer 131 can be selectively formed of a single layer or multiple layers, when necessary.

The display device 100 of one embodiment of the present disclosure operates based on a bottom-emission method in which light emitted from the light emitting element 160 is released to the lower portion of the display device 100. Accordingly, the color filter 140 can be disposed on the passivation layer 131. The color filter 140 converts white light emitted from the light emitting element 160 to red light, green light and blue light. To this end, the color filter 140 is disposed to correspond to the light emitting area of the light emitting element 160. The color filter 140 converts white light emitted from the light emitting element 160 to light of a color corresponding to each of the plurality of sub pixels to embody full colors, thereby enhancing color gamut. In the case where the light emitting element 160 formed in each of the plurality of sub pixels emits red light, green light and blue light, the color filter 140 can be omitted.

The planarization layer 150 is disposed on the thin film transistor 120 and the color filter 140. The planarization layer 150 is disposed on the thin film transistor 120 and the color filter 140 and provides a planar surface. For example, the planarization layer 150 can be made of an organic material. For example, the planarization layer 150 can be comprised of a single layer of polyimide or photo acryl, or multiple layers of polyimide or photo acryl, but not limited thereto. The planarization layer 150 can comprise a contact hole for electrically connecting the thin film transistor 120 and a first electrode 161 of the light emitting element 160.

The light emitting element 160 is disposed on the planarization layer 150. The light emitting element 160 comprises a first electrode 161, an organic light emitting layer 162 and a second electrode 163. The first electrode 161 of the light emitting element 160 electrically connects to the source electrode 123 or the drain electrode 124 of the thin film transistor through the contact hole formed at the planarization layer 150. In the drawing, the first electrode 161 connects to the source electrode 123 electrically but is not limited thereto. The first electrode 161 can also connect to the drain electrode 124 electrically.

The first electrode 161 is disposed on the planarization layer 150. The first electrode 161 can be made of an electrically conductive material of high work function to provide holes to the organic light emitting layer 162. For example, the first electrode 161 can comprise an electrically conductive transparent material such as indium tin oxide (ITO), indium zinc oxide (IZO) and the like, but not be limited thereto.

A bank BNK is disposed on the planarization layer 150 and the first electrode 161. The bank BNK is disposed on the planarization layer 150, in such a way that the bank BNK exposes at least a portion of the first electrode 161. For example, the bank BNK can be disposed on the planarization layer 150 in such a way that the bank BNK covers the edge of the first electrode 161. The bank BNK is an insulation layer that is disposed among the plurality of sub pixels to divide the plurality of sub pixels. Accordingly, an area that is exposed without being covered by the bank BNK can be defined as a light emitting area where light is emitted. The bank BNK can be formed of an organic insulation material. For example, the bank BNK can be made of polyimide, acryl, or benzocyclobutene (BCB)-based resin, but not limited thereto.

The organic light emitting layer 162 is disposed on the first electrode 161. The organic light emitting layer 162 can be an organic layer for emitting light of a specific color. The organic light emitting layer 162 can be formed into one layer that continues across the front surface of the display area. For example, the organic light emitting layer 162 can be configured to emit white light, but not limited thereto. In another example, the organic light emitting layer 162 can be patterned to correspond to each of the plurality of sub pixels. At this time, the organic light emitting layer 162 can be configured to emit light of a color corresponding to each of the plurality of sub pixels. At this time, the color filter 140 can be omitted.

When necessary, the organic light emitting layer 162 can further comprise a variety of layers such as a hole transport layer, a hole injection layer, a hole blocking layer, an electron injection layer, an electron blocking layer, an electron transport layer, and the like selectively.

The second electrode 163 is disposed on the organic light emitting layer 162. The second electrode 163 can be formed into one layer that continues across the front surface of the display area. For example, the second electrode 163 can be a common layer that is formed commonly in the plurality of sub pixels. The second electrode 163 that provides electrons to the organic light emitting layer 162 can be made of an electrically conductive material of low work function. For example, the second electrode 163 can be formed of an electrically conductive transparent material such as indium tin oxide (ITO), indium zinc oxide (IZO) and the like, or metal such as magnesium (Mg), silver (Ag) and the like or an alloy comprising the same and the like, or can further comprise a metal-doped layer, but not limited thereto.

The display device 100 of one embodiment of the present disclosure can comprise an inorganic black matrix BM in which the first black matrix layer BM1 comprising metal oxide and having a refractive index n of 2.1-2.5 and an absorption coefficient k of 0.4-0.6, and the second black matrix layer BM2 formed of metal of low reflexibility are stacked, to effectively block the thin film transistor 120, the capacitors Cst1, Cst2, the data lines DL and the like from being viewed due to the reflection of external light. Accordingly, the reflectance of the back surface of the display device 100 decreases significantly, thereby enhancing a contrast ratio and securing excellent display quality.

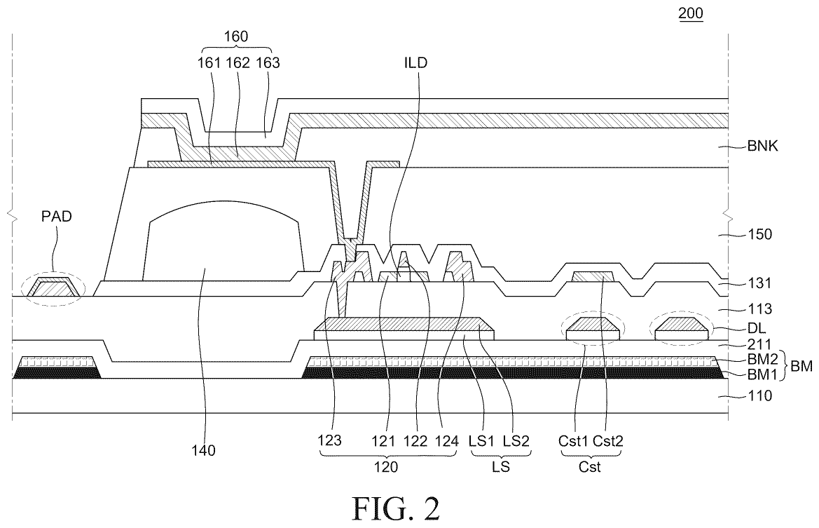

FIG. 2 is a cross-sectional view of a display device of another embodiment of the present disclosure.

Referring to FIG. 2, a display device 200 of another embodiment comprises an array substrate 110, an inorganic black matrix BM, an inorganic film 211, a light shielding layer LS, a second buffer layer 113, a thin film transistor 120, a passivation layer 131, a color filter 140, a planarization layer 150 and a light emitting element 160. The display device 200 illustrated in FIG. 2 is substantially the same as the display device 100 illustrated in FIG. 1 except that the display device 200 is provided with an inorganic film 211 rather than an organic film and is without a first buffer layer. Accordingly, their common features are not described or may be briefly provided.

The inorganic black matrix BM comprising a first black matrix layer BM1 and a second black matrix layer BM2 is disposed on the array substrate 110. The inorganic black matrix BM can be disposed in such a way that the inorganic black matrix BM corresponds to an area of the light emitting element 160 described hereinafter except for a light emitting area thereof. Accordingly, the inorganic black matrix BM prevents components such as a thin film transistor 120, a capacitor Cst, a pad part PAD, various types of lines DL or a planarization layer 150, and the like that have high reflectance from being reflected by external light and viewed by the user. Further, the inorganic black matrix BM prevents deterioration in contrast ratios, caused by reflected light, thereby maintaining high display quality.

The inorganic black matrix BM can be formed to have a multi-layer structure in which the first black matrix layer BM1 and the second black matrix layer BM2 are included. The first black matrix layer BM1 is disposed on the array substrate 110, and the second black matrix layer BM2 is stacked on the first black matrix layer BM1. Since the first black matrix layer BM1 and the second black matrix layer BM2 are stacked as described above, reflectance decreases further, securing an excellent contrast ratio and effectively preventing the thin film transistor 120, the capacitor Cst, various types of lines DL and the like from being reflected and viewed.

For example, the first black matrix layer BM1 can be formed of metal oxide having a refractive index n of 2.1-2.5 and an absorption coefficient k of 0.4-0.6. In the case where the refractive index n and the absorption coefficient k of the first black matrix layer BM1 are within the above ranges, reflectance is low in a broad wavelength band, making it possible to provide a display device of high quality.

For example, the first black matrix layer BM1 can comprise 70-85 wt % of molybdenum oxide (MoOₓ) and 15-30 wt % of niobium oxide (Nb₂O₅) with respect to a total of 100 wt % of metal oxide. In another example, the first black matrix layer BM1 can comprise 75-80 wt % of molybdenum oxide (MoOₓ) and 20-25 wt % of niobium oxide (Nb₂O₅) with respect to a total of 100 wt % of metal oxide. In these range, the refractive index and the absorption coefficient have the above-mentioned ranges, so that reflectance is low, securing an excellent contrast ratio, without a polarization layer that is an expensive component.

For example, the second black matrix layer BM2 can be formed of metal selected from molybdenum (Mo), titanium (Ti) and an alloy thereof. Since the second black matrix layer BM2 formed of the above-described metal and the first black matrix layer BM1 formed of the above-described metal oxide are stacked, a further decrease in reflectance, more excellence in contrast ratios and minimization of the visibility of an electrode or a line of the thin film transistor 120 and the like can be secured, and a display device of high quality can be provided.

The inorganic film 211 is disposed on the inorganic black matrix BM. The inorganic film 211 is formed to have a predetermined thickness and cover the upper surface of the inorganic black matrix BM. The inorganic film 211 can protect the thin film transistor 120 and the light emitting element 160 from moisture, external air, foreign substances and the like infiltrating from the outside. Additionally, the inorganic film 211 can prevent a change in the properties of the thin film transistor 120, caused by dispersion of hydrogen or foreign substance from the array substrate 110 during a process of forming the thin film transistor. For example, the inorganic film 211 can be formed of a material selected from a silicon oxide film, a silicon nitride film and a silicon oxynitride film, but not limited thereto.

For example, the thickness of the inorganic film 211 can be 2000 Å-5000 Å. Within the range, excellent barrier properties and excellent heat resistance can be secured, and the inorganic black matrix BM can be sufficiently covered.

In the case where the inorganic film 211 is disposed on the inorganic black matrix BM as shown in the display device 200 of this embodiment, the first buffer layer can be omitted. Accordingly, the light shielding layer LS can be disposed on the inorganic film 211.

The display device 200 of this embodiment comprises an inorganic black matrix BM in which a first black matrix layer BM1 comprising metal oxide and having a refractive index n of 2.1-2.5 and an absorption coefficient k of 0.4-0.6, and a second black matrix layer BM2 formed of metal of low reflexibility are stacked, to effectively prevent the visibility of components of high reflectance such as a thin film transistor 120 and the like, caused by the reflection of external light. The inorganic black matrix BM of the present disclosure can be disposed in an area of the organic light emitting element 160 except for the light emitting area thereof and decrease reflectance more effectively. Further, without a polarization layer, reflectance is low and a contrast ratio improves significantly, providing a display device 200 incurring less costs and ensuring improvement in display quality.

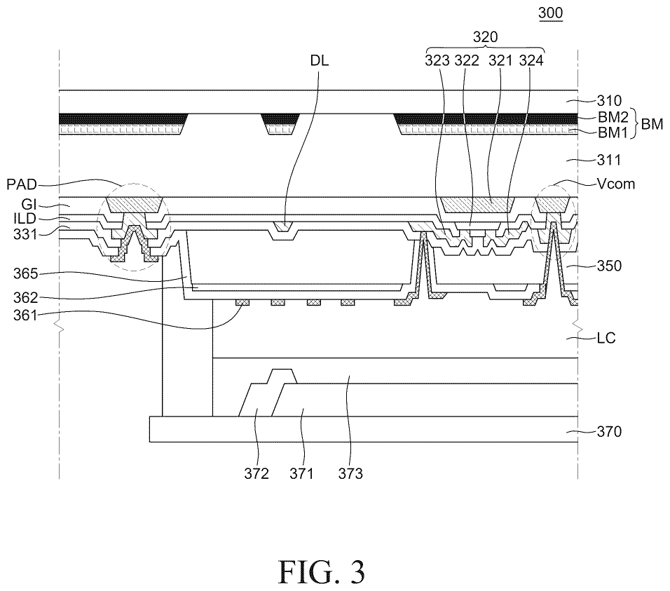

FIG. 3 is a cross-sectional view of a display device of yet another embodiment of the present disclosure.

Referring to FIG. 3, a display device 300 comprises an array substrate 310, an inorganic black matrix BM, an organic film 311, a light shielding layer LS, a thin film transistor 320, a passivation layer 331, a planarization layer 350, a first electrode 361, a second electrode 363, a liquid crystal layer LC, and a color filter substrate 370.

In the display device 300 of this embodiment, pixels are arranged in a matrix form and output an image, and the display device 300 is a liquid crystal display device comprised of an array substrate 310 and a color filter substrate 370 that are bonded with a liquid crystal layer LC therebetween to adjust light transmittance.

In the display device 300 of this embodiment as a borderless liquid crystal display device, a substrate placed in the upper portion of the display device 300 constitutes an array substrate 310, and a substrate placed in the lower portion of the display device 300 constitutes a color filter substrate 370. For example, in the display device 300 of this embodiment, the array substrate 310 having a relatively large surface area is disposed on the color filter substrate 370. Accordingly, the back surfaces of components such as a thin film transistor 320 and a pad part PD formed on the array substrate 310 are disposed to face a display surface of the display device 300, it is possible to remove a structure such as an exterior cover (or a top case) for covering these components. As a result, a four-surface borderless display device can be embodied. At this time, the structure on which the array substrate 110 is placed as described above and which is used as a display surface can be referred to as a flip-over-type display device.

The thin film transistor 320, and various types of lines and electrodes are formed on one surface of the array substrate 310, and define a plurality of sub pixels. A color filter 371 for displaying three primary colors such as red, green and blue, and a black wall 372 partitioning each sub pixel can be formed on the color filter substrate 370. A backlight unit is disposed on the back surface of the color filter substrate 370 and provides light toward the liquid crystal layer LC. Hereinafter, each substrate is described specifically.

First, an inorganic black matrix BM is disposed on one surface of the array substrate 310. The inorganic black matrix BM comprises a first black matrix layer BM and a second black matrix layer BM2 as described above. The inorganic black matrix BM is disposed to overlap each of the thin film transistor 320, the pad part PAD, the data line DL, a common voltage line Vcom that comprise a metal layer of high reflectance. Accordingly, components such as the thin film transistor 320, the pad part PAD, the data line DL, and the common voltage line Vcom are prevented from being reflected by external light and viewed by the user. Additionally, deterioration in contrast ratios, caused by reflected light, can be prevented and high display quality can be maintained.

For example, the first black matrix layer BM1 can be formed of metal oxide having a refractive index n of 2.1-2.5, and an absorption coefficient k of 0.4-0.6. In the case where the refractive index n and absorption coefficient k of the first black matrix layer BM1 are within the above-described ranges, reflectance is low in a broad wavelength band, making it possible to provide a display device of high quality.

For example, the first black matrix layer BM1 can comprise 70-85 wt % of molybdenum oxide (MoOₓ) and 15-30 wt % of niobium oxide (Nb₂O₅) with respect to a total of 100 wt % of metal oxide. In another example, the first black matrix layer BM1 can comprise 75-80 wt % of molybdenum oxide (MoOₓ) and 20-25 wt % of niobium oxide (Nb₂O₅) with respect to a total of 100 wt % of metal oxide. In the ranges of 75-80 wt % of molybdenum oxide (MoOₓ) and 20-25 wt % of niobium oxide (Nb₂O₅), the refractive index and the absorption coefficient are respectively within the ranges of 2.1-2.5 and 0.4-0.6, so that reflectance is low, securing an excellent contrast ratio, without a polarization layer that is an expensive component.

For example, the second black matrix layer BM2 can be formed of metal selected from molybdenum (Mo), titanium (Ti), and an alloy thereof. Since the second black matrix layer BM2 formed of the above-described metal and the first black matrix layer BM1 formed of the above-described metal oxide are stacked, reflectance decreases further, securing excellent in contrast ratios. Additionally, the visibility of components such as a thin film transistor 320 and the like formed of metal having high reflectance is minimized, making it possible to provide a display device of high quality.

The organic film 311 is disposed on the inorganic black matrix BM. The organic film 311 can cover the inorganic black matrix BM, provide a planar surface, and protect the display device 300 from an external impact.

For example, the organic film 311 can be formed to comprise one or more sorts selected from siloxane resin and polyimide. Such a material ensures excellent heat resistance and provides a planar surface, to protect the inorganic black matrix BM during a process of forming the thin film transistor 320, which is performed at high temperature.

For example, the thickness of the organic film 311 can be 2 um-3 um. Within the range, the organic film 311 can cover the inorganic black matrix BM sufficiently and provide a planar surface. In the drawing, the organic film 311 is disposed on the inorganic black matrix BM, but not limited thereto. As described with reference to FIG. 2, an inorganic film can be disposed on the inorganic black matrix BM.

The thin film transistor 320 is disposed on the organic film 311. The thin film transistor 320 is disposed to electrically connect to the first electrode 361 in an area where a gate line and a data line DL cross each other. The thin film transistor 320 comprises a gate electrode 321, an active layer 322, a source electrode 323, and a drain electrode 324.

The gate electrode 321 is disposed on the organic film 311. For example, the gate electrode 321 can be comprised of copper (Cu), aluminum (Al), molybdenum (Mo), nickel (Ni), titanium (Ti), chromium (Cr) or an alloy thereof, but not limited thereto. In this embodiment, the thin film transistor 320 is formed to have a lower gate electrode structure. Accordingly, the gate electrode 321 can block ultraviolet rays input to the active layer 322. Thus, a light shielding layer can be omitted. However, the structure of the thin film transistor 320 may not be limited to the above-described one, and when necessary, can vary.

The active layer 322 is disposed on the gate electrode 321 with a gate insulation film GI between the active layer 322 and the gate electrode 321. The active layer 322 is disposed to overlap the gate electrode 321. The active layer 322 can be an oxide semiconductor layer made of an oxide semiconductor material.

For example, the gate insulation film GI can be formed of a material selected from a silicon oxide film, a silicon nitride film and a silicon oxynitride film, but not limited thereto.

The source electrode 323 and the drain electrode 324 are disposed on the active layer 322 with an insulation film ILD therebetween. Each of the source electrode 323 and the drain electrode 324 is disposed to contact the active layer 322 through a contact hole formed at the insulation film ILD. For example, the source electrode 323 can be disposed to contact the end of one side of the active layer 322, and the drain electrode 324 can be disposed to contact the end of the other side of the active layer 322.

For example, the source electrode 323 and the drain electrode 324 can be comprised of copper (Cu), aluminum (Al), molybdenum (Mo), nickel (Ni), titanium (Ti), chromium (Cr), or an alloy thereof, but not limited thereto.

For example, the insulation film ILD can be formed of a material selected from a silicon oxide film, a silicon nitride film and a silicon oxynitride film, but not limited thereto.

The pad part PAD and the common voltage line Vcom can be disposed on the organic film 311. The pad part PAD can be placed in the non-display area, and the common voltage line Vcom can be placed in the display area. The pad part PAD can be formed in a process the same as those of the source electrode 323, the drain electrode 324 and the gate electrode 321 for convenience of processing. Accordingly, the pad part PAD can be formed of a material the same as those of the source electrode 323, the drain electrode 324 and the gate electrode 321, but not limited thereto.

Further, the common voltage line Vcom can be formed in a process the same as those of the source electrode 323, the drain electrode 324 and the gate electrode 321 for convenience of processing. Accordingly, the common voltage line Vcom can be formed of a material the same as those of the source electrode 323, the drain electrode 324 and the gate electrode 321, but not limited thereto.

The data line DL formed in a process the same as those of the source electrode 323 and the drain electrode 324 can be disposed on the insulation film ILD. Accordingly, the data line DL can be formed of a material the same as those of the source electrode 323 and the drain electrode 324, but not limited thereto.

The passivation layer 331 is disposed on the thin film transistor 320, the pad part PAD, the common voltage line Vcom and the data line DL. The passivation layer 331 can prevent the degradation of the thin film transistor 320, caused by external moisture, oxygen and the like. For example, the passivation layer 331 can be formed of an inorganic insulation material such as a silicon oxide film, a silicon nitride film and the like, but not limited thereto. When necessary, the passivation layer 331 can be formed of a single layer or multiple layers selectively.

The planarization layer 350 is disposed on the passivation layer 331. The planarization layer 350 is formed of an organic material and provides a planar surface. For example, the planarization layer 350 can be comprised of a single layer of polyimide or photoacryl, or multiple layers of polyimide or photoacryl, but not limited thereto. The planarization layer 350 can comprise a contact hole for electrically connecting the thin film transistor 320 and the first electrode 361.

A second electrode 362 as a common electrode is disposed on the planarization layer 350. The second electrode 362 is comprised of one large electrode, and commonly used for sub pixels. In some embodiments, the second electrode 362 can be comprised of a plurality of common electrode blocks. At this time, the common electrode blocks can function as a touch electrode of a capacitive-type touch element, and the display device 300 can be embodied as a display device in which a touch element is built.

For example, the second electrode 362 can be made of an electrically conductive transparent material. For example, the electrically conductive transparent material can be made of tin oxide (TO), indium tin oxide (ITO), indium zinc oxide (IZO), indium zinc tin oxide (ITZO) and the like, but not limited thereto.

A protective layer 365 is disposed on the second electrode 362. The protective layer 365 as a layer for insulating the second electrode 362 and the first electrode 361 can be made of an inorganic insulation material or an organic insulation material. For example, the protective layer 365 can be comprised of a single layer of silicon oxide (SiOx) or silicon nitride (SiNx) or multiple layers of silicon oxide (SiOx) or silicon nitride (SiNx), but not limited thereto.

The first electrode 361 is disposed on the protective layer 133. The first electrode 361 electrically connects to the source electrode 323 or the drain electrode 324 through a contact hole that penetrates the protective layer 365, the planarization layer 350 and the passivation layer 331 under the first electrode 361.

For example, the first electrode 361 can be made of an electrically conductive transparent material. For example, the electrically conductive transparent material can be comprised of tin oxide (TO), indium tin oxide (ITO), indium zinc oxide (IZO), indium zinc tin oxide (ITZO) and the like, but not limited thereto.

A portion of the first electrode 361 is disposed to overlap the second electrode 362. Accordingly, as a voltage is supplied, the liquid crystal molecules of the liquid crystal layer LC are rotated based on dielectric anisotropy by an electric field formed between the first electrode 361 and the second electrode 362, and the transmittance of light passing through the display area changes depending on a degree to which the liquid crystals are rotated. By doing so, the amount of light of the sub pixels can be controlled.

The color filter substrate 370 is disposed to face the array substrate 110. The color filter 371 and the black wall 372 can be formed on the color filter substrate 370. The color filter 371 can be comprised of red, green and blue color filters comprising red, green and blue dyes. The color filters are used to absorb or transmit light of a specific wavelength to display red, green and blue. The black wall 372 is formed to correspond to the boundary of each sub pixel and partitions each sub pixel. Additionally, the black wall 372 can be formed to correspond to the non-display area.

An overcoating layer 373 is disposed to cover the color filter 371 and the black wall 372. The over coating layer 373 can cover the color filter 371 and the black wall 372 and provide a planar surface.

A spacer for maintaining a gap between the array substrate 310 and the color filter substrate 370 can be disposed between the array substrate 310 and the color filter substrate 370. The liquid crystal layer LC is disposed in the gap between the array substrate 310 and the color filter substrate 370, which is formed by the spacer. The liquid crystal layer LC is a layer that comprises liquid crystals and is capable of transmitting and blocking light by an electric field. Specifically, the liquid crystal layer LC changes light transmittance by an electric field generated by the first electrode 361 and the second electrode 362 to display an image.

The display device 300 of this embodiment is a display device having a flip-over structure where the back surface of an array substrate 310 is viewed. At this time, a structure such as an exterior cover for covering a component such as a pad part PAD formed in the non-display area of the array substrate 310 can be removed, making it possible to embody a four-surface borderless display device. However, components such as a pad part PAD, a thin film transistor 320 and the like are formed toward a viewing surface, is visible from the outside and has high reflectance. As such, an existing display device having a flip-over structure is provided with a polarization layer on the viewing surface of the array substrate 310. However, in the display device 300 of the present disclosure, the inorganic black matrix BM where the first black matrix layer BM1 and the second black matrix layer BM2 are stacked is formed on one surface of the array substrate 310, leading to a significant decrease in reflectance. Accordingly, without a polarization layer, reflectance is low, an excellent contrast ratio is secured, and components such as a thin film transistor 320 and the like are not viewed, securing excellent display quality.

Hereinafter, effects of the subject matter of the present disclosure are described specifically with reference to embodiments and comparative examples. However, the embodiments described hereinafter are provided only as examples, and are not intended to limit the scope of the present disclosure.

### Experimental Example 1

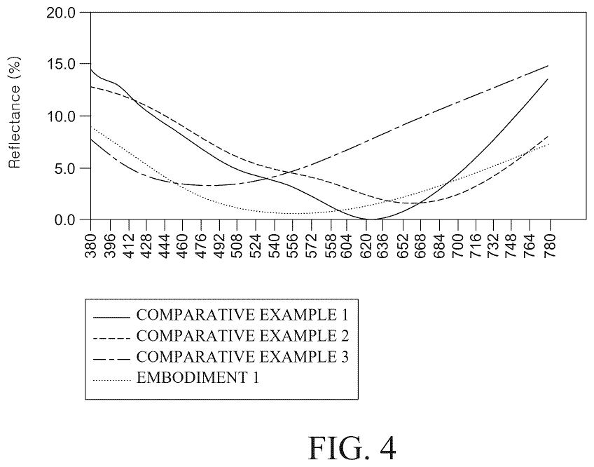

Reflectance was simulated with respect to an inorganic black matrix where a first black matrix layer having refractive indices and absorption coefficients shown in Table 1 hereinafter by mixing molybdenum oxide (MoOx) and niobium oxide (Nb₂O₅), and a second black matrix layer comprising Cu or MoTi metal on the first black matrix layer were stacked. Following results are shown in Table 1 and FIG. 4.

Particularly, FIG. 4 is a graph showing reflectance of the wavelength of each of Comparative examples 1-3 and Embodiment 1. Here, Embodiment 1 is an example embodiment of the present disclosure.

TABLE 1

| | | Comparative | Comparative | Comparative | Embodiment |
|---|---|---|---|---|---|
| | | example 1 | example 2 | example 3 | 1 |
| First black | Refractive | 2.7 | 2.3 | 2.7 | 2.3 |
| matrix layer | index | | | | |
| | Absorption | 0.8 | 0.6 | 0.8 | 0.6 |
| | coefficient | | | | |

| | | | | |
|---|---|---|---|---|
| Second black matrix layer | Cu | Cu | MoTi | MoTi |
| Reflectance | 5.7% | 5.7% | 7.3% | 3.2% |

Referring to Table 1 and FIG. 4 together, in the case of an inorganic black matrix of Embodiment 1 where a first black matrix layer having a refractive index of 2.3 and an absorption coefficient of 0.6 and a second black matrix formed of MoTi are stacked, reflectance is 3.2% that is the lowest.

In the case of an inorganic black matrix of Comparative example 2 where a first black matrix layer the same as that of Embodiment 1 and a second black matrix layer comprising Cu are stacked, reflectance is much higher than that of the embodiment.

Additionally, Comparative example 1 and Comparative example 3 where the refractive index and absorption coefficient of a first black matrix layer are outside the range of the present disclosure have much greater reflectance than the embodiment. In particular, although Comparative example 3 comprises a second black matrix layer formed of MoTi like Embodiment 1, the reflectance of Comparative example 3 is the highest.

Thus, in the case where a display device comprises an inorganic black matrix in which a first black matrix layer having a refractive index of 2.3 and an absorption coefficient of 0.6 and a second black matrix layer formed of MoTi are stacked, the reflectance of the display device can decrease significantly. In particular, in the case of Embodiment 1, reflectance is low in a broad wavelength band entirely, significantly contributing to a decrease in the reflectance of a display device and improvement in display quality.

### Experimental Example 2

In an inorganic black matrix where a first black matrix layer under conditions shown in Table 2 hereinafter and a second black matrix layer formed of MoTi were stacked, reflectance was simulated depending on the refractive index n, absorption coefficient k and thickness of the first black matrix layer.

TABLE 2

k

| n | 0.2 | 0.4 | 0.6 | 0.8 | 1.0 | 1.2 | Thickness (Å) |
|---|---|---|---|---|---|---|---|
| 2.3 | 7.8 | 3.5 | 3.2 | 4.9 | 7.6 | 10.9 | 600 |
| 2.5 | 6.6 | 3.7 | 3.9 | 5.8 | 8.4 | 11.6 | 500 |
| 2.7 | 7.7 | 4.7 | 4.7 | 6.3 | 8.8 | 11.7 | 500 |
| 2.9 | 5.8 | 4.5 | 5.3 | 7.3 | 9.8 | 12.8 | 400 |

Referring to Table 2, in the case where a first black matrix layer and a second black matrix layer formed of MoTi are stacked, reflectance is 3% that is significantly low, at the refractive index of 2.3 and 2.5 and the absorption coefficient of 0.4 and 0.6 of the first black matrix layer.

Additionally, in an inorganic black matrix where a first black matrix layer under conditions shown in Table 3 hereinafter, and a second black matrix layer formed of Mo were stacked, reflectance was simulated depending on the refractive index n, absorption coefficient K and thickness of the first black matrix layer.

TABLE 3

k

| n | 0.2 | 0.4 | 0.6 | 0.8 | 1.0 | 1.2 | Thickness (Å) |
|---|---|---|---|---|---|---|---|
| 2.3 | 7.9 | 3.2 | 2.7 | 4.4 | 7.1 | 10.4 | 600 |
| 2.5 | 6.5 | 3.2 | 3.3 | 5.1 | 7.8 | 10.9 | 500 |
| 2.7 | 7.7 | 4.3 | 4.2 | 5.7 | 8.2 | 11.1 | 500 |
| 2.9 | 5.4 | 3.8 | 4.5 | 6.4 | 9.0 | 11.9 | 400 |

Referring to Table 3, in the case where a first black matrix layer and a second black matrix layer formed of Mo are stacked, reflectance is 2%-3% that are significantly low, at the refractive index of 2.3 and 2.5 and the absorption coefficient of 0.4 and 0.6 of the first black matrix layer.

Additionally, in an inorganic black matrix where a first black matrix layer under conditions shown in Table 4 hereinafter, and a second black matrix layer formed of Al were stacked, reflectance was simulated depending on the refractive index n, absorption coefficient K and thickness of the first black matrix layer.

TABLE 4

| | k | | | | | | |
|---|---|---|---|---|---|---|---|
| n | 0.2 | 0.4 | 0.6 | 0.8 | 1.0 | 1.2 | Thickness (Å) |
| 2.3 | 31.6 | 12.8 | 5.7 | 4.3 | 5.6 | 8.3 | 600 |
| 2.5 | 32.7 | 14.6 | 7.2 | 5.3 | 6.1 | 8.4 | 500 |
| 2.7 | 33.2 | 15.3 | 7.8 | 5.7 | 6.3 | 8.5 | 500 |
| 2.9 | 33.3 | 16.5 | 9.1 | 6.7 | 6.9 | 8.7 | 400 |

Referring to Table 4, in the case where a first black matrix layer and a second black matrix layer formed of Al are stacked, reflectance is greater than that of an inorganic black matrix comprising a second black matrix layer formed of Mo and MoTi.

Additionally, in an inorganic black matrix where a first black matrix layer under conditions shown in Table 5 hereinafter, and a second black matrix layer formed of Cu were stacked, reflectance was simulated depending on the refractive index n, absorption coefficient K and thickness of the first black matrix layer.

TABLE 5

| | k | | | | | | |
|---|---|---|---|---|---|---|---|
| n | 0.2 | 0.4 | 0.6 | 0.8 | 1.0 | 1.2 | Thickness (Å) |
| 2.3 | 28.2 | 11.8 | 5.7 | 4.6 | 5.9 | 8.6 | 600 |
| 2.5 | 29.4 | 13.3 | 6.8 | 5.1 | 6.0 | 8.3 | 500 |
| 2.7 | 29.7 | 14.5 | 7.8 | 5.7 | 6.2 | 8.1 | 500 |
| 2.9 | 32.6 | 16.8 | 9.8 | 7.3 | 7.4 | 9.0 | 400 |

Referring to Table 5, in the case where a first black matrix layer and a second black matrix layer formed of Cu are stacked, reflectance is greater than that of an inorganic black matrix comprising a second black matrix layer formed of Mo and MoTi.

Accordingly, although the first black matrix layer has the same refractive index and absorption coefficient, reflectance varies depending on a material for the second black matrix layer. In summary, in the case of a display device comprising an inorganic black matrix where a first black matrix layer having a refractive index of 2.3-2.5 and an absorption coefficient of 0.4-0.6 and a second black matrix layer formed of Mo or MoTi are stacked, the reflectance of the display device Can decrease significantly.

The example embodiments of the present disclosure can also be described as follows:

According to an aspect of the present disclosure, a display device comprises: an array substrate; an inorganic black matrix disposed on the array substrate; and a thin film transistor disposed on the inorganic black matrix, wherein at least a portion of the inorganic black matrix overlaps the thin film transistor, the inorganic black matrix comprises a first black matrix layer on the array substrate and a second black matrix layer on the first black matrix layer, the first black matrix layer comprises metal oxide, a reflective index n of the first black matrix layer is 2.1-2.5, and an absorption coefficient k of the first black matrix layer is 0.4-0.6.

The first black matrix layer can comprise molybdenum oxide (MoOₓ) and niobium oxide (Nb₂O₅).

The first black matrix layer can comprise 70-85 wt % of molybdenum oxide (MoOₓ) and 15-30 wt % of niobium oxide (Nb₂O₅) with respect to 100 wt % of the metal oxide.

The second black matrix layer can comprise metal selected from molybdenum (Mo), titanium (Ti) and an alloy thereof.

A thickness of the first black matrix layer can be 300 Å-700 Å, and a thickness of the second black matrix layer can be 500 Å-3000 Å.

The display device can further comprise an organic film or an inorganic film disposed to cover the black matrix, and the thin film transistor can be disposed on the organic film or the inorganic film.

The display device can further comprise: a light shielding layer disposed to overlap the thin film transistor between the organic film or the inorganic film and the thin film transistor; a passivation layer disposed to cover the thin film transistor; a planarization layer disposed on the passivation layer; an organic light emitting element disposed on the planarization layer; and a color filter disposed on the passivation layer to overlap a light emitting area of the organic light emitting element, wherein the black matrix can be disposed in an area of the organic light emitting element except for the light emitting area thereof.

The organic film can have a planar surface, and a thickness of the organic film can be 2 um-3 um.

The organic film can comprise one or more sorts selected from siloxane resin and polyimide.

A thickness of the inorganic film can be 2000 Å-5000 Å.

The display device can further comprise: a passivation layer disposed to cover the thin film transistor; a planarization layer disposed on the passivation layer; a first electrode disposed on the planarization layer and connected to the thin film transistor; a second electrode disposed on the planarization layer and disposed to overlap the first electrode; a color filter substrate disposed to face the array substrate; and a liquid crystal layer disposed between the first electrode and the color filter substrate.

The thin film transistor can comprise an oxide semiconductor layer.

The inorganic black matrix can be disposed to contact the array substrate directly.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
an array substrate;
an inorganic black matrix disposed on the array substrate; and
a thin film transistor disposed on the inorganic black matrix,
wherein at least a portion of the inorganic black matrix overlaps the thin film transistor,
the inorganic black matrix comprises a first black matrix layer on the array substrate and a second black matrix layer on the first black matrix layer,
the first black matrix layer comprises metal oxide,
a reflective index n of the first black matrix layer is about 2.1-2.5, and
an absorption coefficient k of the first black matrix layer is about 0.4-0.6.

2. The display device of claim 1, wherein the first black matrix layer comprises molybdenum oxide (MoOₓ) and niobium oxide (Nb₂O₅).

3. The display device of claim 2, wherein the first black matrix layer comprises 70-85 wt % of molybdenum oxide (MoOₓ) and 15-30 wt % of niobium oxide (Nb₂O₅) with respect to 100 wt % of the metal oxide.

4. The display device of claim 1, wherein the second black matrix layer comprises metal selected from molybdenum (Mo), titanium (Ti) and an alloy thereof.

5. The display device of claim 1, wherein a thickness of the first black matrix layer is 300 Å-700 Å, and a thickness of the second black matrix layer is 500 Å-3000 Å.

6. The display device of claim 1, wherein the display device further comprises an organic film or an inorganic film disposed to cover the black matrix, and
the thin film transistor is disposed on the organic film or the inorganic film.

7. The display device of claim 6, further comprising:
a light shielding layer disposed to overlap the thin film transistor between the organic film or the inorganic film and the thin film transistor;
a passivation layer disposed to cover the thin film transistor;
a planarization layer disposed on the passivation layer;
an organic light emitting element disposed on the planarization layer; and
a color filter disposed on the passivation layer to overlap a light emitting area of the organic light emitting element,
wherein the black matrix is disposed in an area of the organic light emitting element except for the light emitting area thereof.

8. The display device of claim 6, wherein the organic film has a planar surface, and a thickness of the organic film is 2 um-3 um.

9. The display device of claim 6, wherein the organic film comprises one or more sorts selected from siloxane resin and polyimide.

10. The display device of claim 6, wherein a thickness of the inorganic film is 2000 Å-5000 Å.

11. The display device of claim 6, further comprising:
a passivation layer disposed to cover the thin film transistor;
a planarization layer disposed on the passivation layer;
a first electrode disposed on the planarization layer and connected to the thin film transistor;
a second electrode disposed on the planarization layer and disposed to overlap the first electrode;
a color filter substrate disposed to face the array substrate; and
a liquid crystal layer disposed between the first electrode and the color filter substrate.

12. The display device of claim 1, wherein the thin film transistor comprises an oxide semiconductor layer.

13. The display device of claim 1, wherein the inorganic black matrix is disposed to contact the array substrate directly.
